(19) United States
(12) Patent Application Publication
(10) Pub. No.: US 2012/0274417 A1
(43) Pub. Date: Nov. 1, 2012

(54) MULTIPLEXER

(75) Inventors: Takashi KIHARA, Nagaokakyo-shi (JP); Toru EIHAMA, Nagaokakyo-shi (JP)

(73) Assignee: MURATA MANUFACTURING CO., LTD., Nagaokakyo-shi (JP)

(21) Appl. No.: 13/543,908

(22) Filed: Jul. 9, 2012

Related U.S. Application Data
(63) Continuation of application No. PCT/JP2010/061603, filed on Jul. 8, 2010.

(30) Foreign Application Priority Data
Jan. 13, 2010 (JP) 2010-004997

(51) Int. Cl. H03H 9/72

(52) U.S. Cl. 333/133

(57) ABSTRACT

A multiplexer that includes three or more band-pass filters having different pass bands and has a reduced size, includes a duplexer and a third band-pass filter connected to an antenna terminal, the duplexer and the third band-pass filter are connected in parallel, the duplexer includes a first band-pass filter having a first pass band and a second band-pass filter having a second pass band different from the first pass band, and the third band-pass filter has a third pass band different from the first and second pass bands.

### BACKGROUND OF THE INVENTION

1. Field of the Invention

The present invention relates to a multiplexer included in a communication device, such as a cellular phone, and connected to an antenna. In particular, the present invention relates to a multiplexer that includes three or more band-pass filters.

2. Description of the Related Art

In recent years, there has been a rapid growth in the number of subscribers to cellular phone services. At the same time, global roaming has been widespread which allows the use of cellular phone services anywhere in the world. Additionally, the volume of various types of content transmitted and received by cellular phones has been increased rapidly. To improve communication quality while responding to these changes, cellular phones are required to support multiple bands and multiple types of communication systems.

Cellular phones that support CDMA, such as the universal mobile telecommunications system (UMTS), transmit and receive signals simultaneously. For this, an RF circuit of a cellular phone includes a duplexer. A duplexer is a branching filter that includes a transmitting filter, a receiving filter, and a matching circuit. A cellular phone that supports CDMA includes a plurality of such duplexers to support multiple types of communication systems. That is, duplexers that support different bands and communication systems to be used are included in the cellular phone. However, including a plurality of duplexers in the cellular phone undesirably increases the size of the RF circuit.

To reduce the size of the RF circuit, the receiving filter and the transmitting filter may be shared by multiple communication systems.

UMTS-BAND1 has a transmitting band ranging from 1920 MHz to 1980 MHz and a receiving band ranging from 2110 MHz to 2170 MHz. UMTS-BAND4 has a transmitting band ranging from 1710 MHz to 1755 MHz and a receiving band ranging from 2110 MHz to 2155 MHz. UMTS-BAND10 has a transmitting band ranging from 1710 MHz to 1770 MHz and a receiving band ranging from 2110 MHz to 2170 MHz. Thus, the receiving bands of UMTS-BAND1 and UMTS-BAND4 have a common frequency band. Also, the receiving bands of UMTS-BAND1 and UMTS-BAND10 have a common frequency band. In this case, two different bands may share the same receiving filter.

For example, instead of using different duplexers for UMTS-BAND1 and UMTS-BAND4, a cellular phone that supports UMTS-BAND1 and UMTS-BAND4 may use a triplexer that includes the following three band-pass filters: a transmitting filter for UMTS-BAND1, a transmitting filter for UMTS-BAND4, and a receiving filter for both UMTS-BAND1 and UMTS-BAND4. Using such a triplexer can reduce the size of an RF circuit. A triplexer is a branching filter that includes three band-pass filters and three matching circuits.

Japanese Unexamined Patent Application Publication No. 2005-57342 discloses such a triplexer.

FIG. 5 is a schematic circuit diagram of a triplexer described in Japanese Unexamined Patent Application Publication No. 2005-57342.

A triplexer 101 includes an antenna terminal 103 connected to an antenna 102. A first matching circuit 104, a second matching circuit 105, and a third matching circuit 106 are connected in parallel with each other to the antenna terminal 103. A first band-pass filter 107, a second band-pass filter 108, and a third band-pass filter 109 are connected in series to the first matching circuit 104, the second matching circuit 105, and the third matching circuit 106, respectively. The first band-pass filter 107, the second band-pass filter 108, and the third band-pass filter 109 are connected to a first terminal 110, a second terminal 111, and a third terminal 112, respectively.

The first, second, and third band-pass filters 107, 108, and 109 have different pass bands. In each of the first, second, and third band-pass filters 107, 108, and 109, insertion loss is small in its pass band and attenuation is large in its attenuation band. In the pass band of each of the first, second, and third band-pass filters 107, 108, and 109, the phases of the other two band-pass filters need to be in an open state. Therefore, for example, the phase of the first band-pass filter 107 needs to be in an open state in the pass bands of the second and third band-pass filters 108 and 109.

However, due to the design of the band-pass filter, it is very difficult to adjust the phase to be in an open state in the pass bands of the other two band-pass filters.

In the triplexer 101, the first, second, and third matching circuits 104, 105, and 106 are connected between the antenna terminal 103 and the first, second, and third band-pass filters 107, 108, and 109. Connecting the first, second, and third matching circuits 104, 105, and 106 enables the phase of each of the first, second, and third band-pass filters 107, 108, and 109 to be in an open state in the pass bands of the other two band-pass filters. For example, connecting the first matching circuit 104 to the first band-pass filter 107 enables the phase of the first band-pass filter 107 to be in an open state in the pass bands of the second and third band-pass filters 108 and 109. The first, second, and third matching circuits 104, 105, and 106 each are formed by a delay line, a capacitor, and/or an inductor.

The triplexer 101 requires the first, second, and third matching circuits 104, 105, and 106 to be connected to the first, second, and third band-pass filters 107, 108, and 109, respectively. This increases the number of components and the size of the triplexer 101.

### SUMMARY OF THE INVENTION

Preferred embodiments of the present invention provide a multiplexer that can easily support multiple bands and multiple types of communication systems and is smaller in size.

A multiplexer according to a preferred embodiment of the present invention includes an antenna terminal, a duplexer including a first band-pass filter and a second band-pass filter, and a third band-pass filter. The first band-pass filter has a first pass band, the second band-pass filter has a second pass band different from the first pass band, and the third band-pass filter has a third pass band different from the first and second pass bands. The duplexer and the third band-pass filter are connected in parallel with each other to the antenna terminal.

In a specific aspect of the multiplexer according to a preferred embodiment of the present invention, the third pass band is lower or higher than the first and second pass bands.

In another specific aspect of the multiplexer according to a preferred embodiment of the present invention, the multiplexer further includes a first matching circuit connected between the duplexer and the antenna terminal.

In still another specific aspect of the multiplexer according to a preferred embodiment of the present invention, the third pass band is lower than the first and second pass bands, and the first matching circuit is a high-pass filter.

In still another specific aspect of the multiplexer according to a preferred embodiment of the present invention, the third pass band is higher than the first and second pass bands, and the first matching circuit is a low-pass filter.

In still another specific aspect of the multiplexer according to a preferred embodiment of the present invention, the multiplexer further includes a second matching circuit connected between the third band-pass filter and the antenna terminal.

In still another specific aspect of the multiplexer according to a preferred embodiment of the present invention, phases of the first and second band-pass filters of the duplexer as viewed from the antenna terminal are in an open state in the third pass band, and a phase of the third band-pass filter as viewed from the antenna terminal is in an open state in the first and second pass bands. Thus, since there is no need to provide a matching circuit between the duplexer and the antenna terminal and between the third band-pass filter and the antenna terminal, it is possible to further reduce the size of the multiplexer.

In the multiplexer according to various preferred embodiments of the present invention, the duplexer including the first and second band-pass filters and the third band-pass filter are connected in parallel with each other to the antenna terminal. This can reduce the size of the multiplexer. For example, in the triplexer described in Japanese Unexamined Patent Application Publication No. 2005-57342, it is necessary to connect the first, second, and third matching circuits to the first, second, and third band-pass filters, respectively. In contrast, in a preferred embodiment of the present invention where the triplexer includes the duplexer including the first and second band-pass filters and the third band-pass filter, the number of matching circuits is smaller than that in the triplexer of the related art. It is thus possible to reduce the size of the multiplexer.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic circuit diagram of a multiplexer according to a first preferred embodiment of the present invention.

FIG. 2 is a schematic circuit diagram of a multiplexer according to a second preferred embodiment of the present invention.

FIG. 3 is a schematic circuit diagram of a multiplexer according to a third preferred embodiment of the present invention.

FIG. 4 is a schematic circuit diagram of a multiplexer according to a fourth preferred embodiment of the present invention.

FIG. 5 is a schematic circuit diagram for describing a triplexer of the related art.

### DETAILED DESCRIPTION OF THE PREFERRED EMBODIMENTS

The present invention will now be explained by describing specific preferred embodiments of the present invention with reference to the drawings.

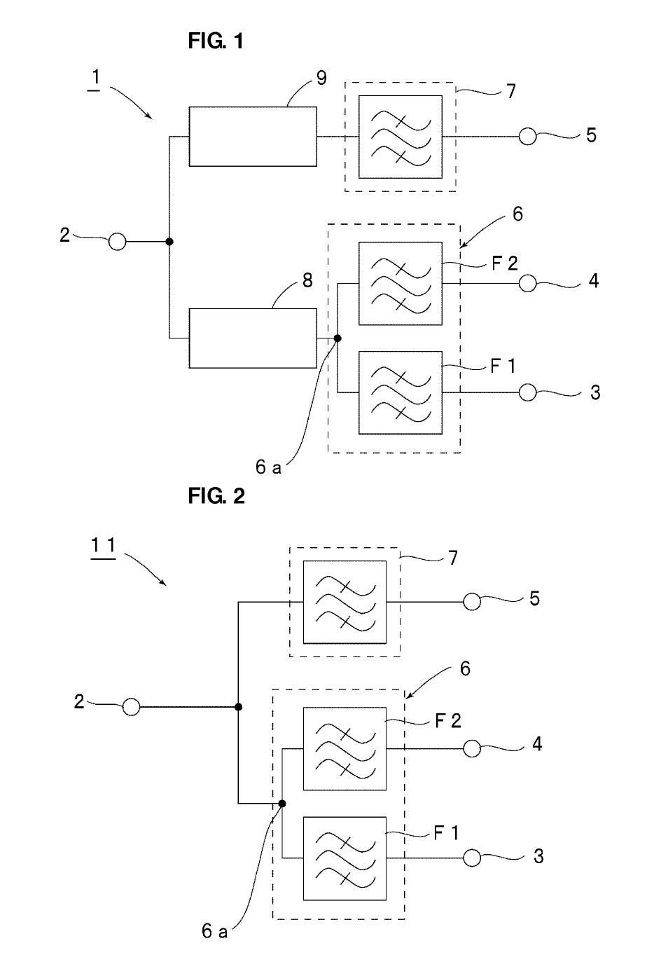

FIG. 1 is a schematic circuit diagram of a multiplexer according to a first preferred embodiment of the present invention.

The multiplexer 1 includes an antenna terminal 2, a first terminal 3, a second terminal 4, and a third terminal 5. A duplexer 6 is connected between the antenna terminal 2 and the first and second terminals 3 and 4. The duplexer 6 includes a first band-pass filter F1 and a second band-pass filter F2. The first band-pass filter F1 has a pass band different from that of the second band-pass filter F2. The first band-pass filter F1 is connected between a common connection point 6a of the duplexer 6 and the first terminal 3. The second band-pass filter F2 is connected between the common connection point 6a of the duplexer 6 and the second terminal 4.

A third band-pass filter 7 is connected between the antenna terminal 2 and the third terminal 5. That is, the third band-pass filter 7 is connected in parallel with the duplexer 6.

The third band-pass filter 7 has a pass band different from those of the first and second band-pass filters F1 and F2. That is, the multiplexer 1 is a triplexer that includes three band-pass filters having different pass bands.

The pass band of the first band-pass filter F1 will be referred to as a first pass band, the pass band of the second band-pass filter F2 will be referred to as a second pass band, and the pass band of the third band-pass filter 7 will be referred to as a third pass band. In the present preferred embodiment, the first, second, and third pass bands have the following relationship: third pass band<second pass band<first pass band. That is, the third pass band is located on the lowest frequency side and the first pass band is located on the highest frequency side. In other words, the second pass band is located in the middle of the first, second, and third pass bands.

In the present preferred embodiment, a first matching circuit 8 is connected between the antenna terminal 2 and the duplexer 6. A second matching circuit 9 is connected between the antenna terminal 2 and the third band-pass filter 7.

The second matching circuit 9 is configured such that the phase of the third band-pass filter 7 in an open state in the first and second pass bands, which are the pass bands of the first and second band-pass filters F1 and F2 of the duplexer 6.

The first matching circuit 8 is configured such that the phases of the first and second band-pass filters F1 and F2 of the duplexer 6 are in an open state in the third pass band, which is the pass band of the third band-pass filter 7.

The first and second matching circuits 8 and 9 each preferably include a delay line, a capacitor, and an inductor. The delay line, capacitor, and inductor may be chip components. Alternatively, the delay line, capacitor, and inductor may be wires and comb-shaped electrodes on a substrate constituting the multiplexer 1, for example.

In the duplexer 6, the phase of the first band-pass filter F1 is in an open state in the second pass band, which is the pass band of the second band-pass filter F2. The phase of the second band-pass filter F2 is in an open state in the first pass band, which is the pass band of the first band-pass filter F1.

In the triplexer 101 of the related art illustrated in FIG. 5, the first, second, and third band-pass filters 107, 108, and 109 are connected in parallel with each other to the antenna terminal 103. At the same time, the first, second, and third matching circuits 104, 105, and 106 are connected to the first, second, and third band-pass filters 107, 108, and 109, respectively. This means that the triplexer 101 of the related art requires three matching circuits (first, second, and third matching circuits 104, 105, and 106) as well as three band-pass filters (first, second, and third band-pass filters 107, 108, and 109). That is, the triplexer 101 of the related art requires as many matching circuits as there are band-pass filters. This increases the number of components and makes it difficult to reduce the size of the triplexer 101.

In the multiplexer 1 of the present preferred embodiment, the triplexer preferably includes the duplexer 6, the third band-pass filter 7, and the first and second matching circuits 8 and 9. Although including three band-pass filters (first and second band-pass filters F1 and F2 and third band-pass filter 7), the multiplexer 1 can realize desired characteristics with two matching circuits (first and second matching circuits 8 and 9). The number of matching circuits can thus be made smaller than that in the triplexer 101 of the related art. This can reduce the size of the multiplexer 1.

In the present preferred embodiment, the first and second band-pass filters F1 and F2 of the duplexer 6 and the third band-pass filter 7 are surface acoustic wave filters. The first, second, and third band-pass filters F1, F2, and 7 may be other types of band-pass filters, such as boundary acoustic wave filters or piezoelectric thin-film filters.

In the present preferred embodiment, the third pass band, which is the pass band of the third band-pass filter 7, is lower than the first and second pass bands, which are the pass bands of the first and second band-pass filters F1 and F2 of the duplexer 6. However, the present invention is not limited to this. The third pass band, which is the pass band of the third band-pass filter 7, may be higher than the first and second pass bands, which are the pass bands of the first and second band-pass filters F1 and F2 of the duplexer 6. That is, it is only necessary that the band-pass filter having a pass band located in the middle of the first, second, and third pass bands be either one of the first and second band-pass filters F1 and F2 of the duplexer 6.

If the third pass band is located in the middle of the first, second, and third pass bands, one of the first and second band-pass filters F1 and F2 of the duplexer 6 has a pass band higher than the third pass band, and the other has a pass band lower than the third pass band. In this case, the phase of the third band-pass filter 7 needs to be in an open state both in the pass band lower than the third pass band and the pass band higher than the third pass band. Therefore, it is necessary to rapidly change the reflected impedance of the third band-pass filter 7. However, it is very difficult to rapidly change the reflected impedance of the third band-pass filter 7.

On the other hand, if the highest or lowest of the first, second, and third pass bands is the third pass band, the band-pass filter having a pass band located in the middle is either one of the first and second band-pass filters F1 and F2 of the duplexer 6. In this case, the phase of the third band-pass filter 7 needs to be in an open state either in the two pass bands lower than the third pass band or in the two pass bands higher than the third pass band. Thus, without rapidly changing the reflected impedance of the third band-pass filter 7, the phase of the third band-pass filter 7 can be easily brought into an open state. Therefore, it is preferable, as in the preferred embodiment described above, that either the first pass band or the second pass band be located in the middle of the first, second, and third pass bands. In other words, it is preferable that the band-pass filter having a pass band located in the middle of the first, second, and third pass bands be either one of the first band-pass filter F1 and the second band-pass filter F2.

FIG. 2 is a schematic circuit diagram of a multiplexer according to a second preferred embodiment of the present invention.

The configuration of the multiplexer 11 is the same as that of the multiplexer 1 of the first preferred embodiment except that the multiplexer 11 does not include the first and second matching circuits 8 and 9 of the multiplexer 1. Therefore, the description of components identical to those of the first preferred embodiment will be omitted by assigning the same reference numerals as those in the first preferred embodiment and referring to the description of the first preferred embodiment.

In the multiplexer 11, no matching circuit is connected to either of the duplexer 6 and the third band-pass filter 7. The first and second band-pass filters F1 and F2 and the third band-pass filter 7 preferably are surface acoustic wave filters. In each of the first and second band-pass filters F1 and F2 and the third band-pass filter 7, the electrode finger pitch and the capacity ratio of IDT electrodes defining the surface acoustic wave filter are adjusted, so that the phase of each of the first and second band-pass filters F1 and F2 and the third band-pass filter 7 is brought into a desired state. Specifically, by adjusting the electrode finger pitch and the capacity ratio of IDT electrodes of the third band-pass filter 7, the phase of the third band-pass filter 7 as viewed from the antenna terminal 2 is brought into an open state in the first and second pass bands, which are the pass bands of the first and second band-pass filters F1 and F2 of the duplexer 6. Also, by adjusting the electrode finger pitch and the capacity ratio of IDT electrodes of each of the first and second band-pass filters F1 and F2 of the duplexer 6, the phases of the first and second band-pass filters F1 and F2 as viewed from the antenna terminal 2 are brought into an open state in the third pass band, which is the pass band of the third band-pass filter 7.

As described above, in each of the first and second band-pass filters F1 and F2 and the third band-pass filter 7, the electrode finger pitch and the capacity ratio of IDT electrodes defining the surface acoustic wave filter may be adjusted, so that the phase of the band-pass filter as viewed from the antenna terminal 2 is brought into an open state in the pass bands of the other band-pass filters. Since this does not involve the use of any matching circuits, the multiplexer 11 having a smaller size can be realized.

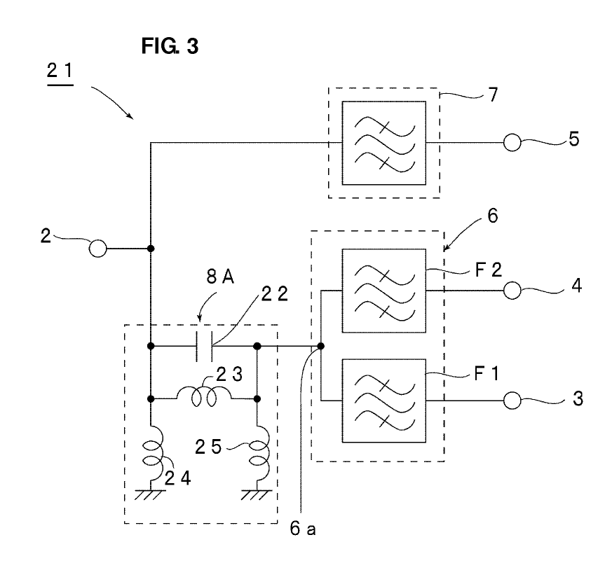

FIG. 3 is a schematic circuit diagram of a multiplexer according to a third preferred embodiment of the present invention.

The configuration of the multiplexer 21 is preferably the same as that of the multiplexer 1 of the first preferred embodiment, except that a matching circuit 8A is connected between the antenna terminal 2 and the duplexer 6 and that no matching circuit is connected between the antenna terminal 2 and the third band-pass filter 7. Therefore, the description of components identical to those of the first preferred embodiment will be omitted by assigning the same reference numerals as those in the first preferred embodiment and referring to the description of the first preferred embodiment.

As is apparent from the description of the second preferred embodiment, the present invention can omit the use of a matching circuit by adjusting, in each of the first and second band-pass filters F1 and F2 and/or the third band-pass filter 7 which are surface acoustic wave filters, the electrode finger pitch and the capacity ratio of IDT electrodes defining the surface acoustic wave filter. In the present preferred embodiment, by adjusting the electrode finger pitch and the capacity ratio of IDT electrodes of the third band-pass filter 7, the phase of the third band-pass filter 7 is brought into an open state in the first and second pass bands, which are the pass bands of the first and second band-pass filters F1 and F2 of the duplexer 6.

In the present preferred embodiment, the matching circuit 8A is connected between the antenna terminal 2 and the duplexer 6. The matching circuit 8A includes a first capacitor and first, second, and third inductors 23, 24, and 25. Specifically, the first capacitor 22 is connected between the antenna terminal 2 and the common connection point 6a of the duplexer 6. The first inductor 23 is connected in parallel with the first capacitor 22. The second inductor 24 is connected between the antenna terminal 2 and the ground potential. The third inductor 25 is connected between the common connection point 6a and the ground potential.

The matching circuit 8A is configured such that the phases of the first and second band-pass filters F1 and F2 of the duplexer 6 are in an open state in the third pass band, which is the pass band of the third band-pass filter 7. The matching circuit 8A includes an LC resonance circuit including the first capacitor 22 and the first inductor 23, and the second and third inductors 24 and 25 connected in parallel. The matching circuit 8A thus functions as a high-pass filter.

Therefore, the multiplexer 21 is effective when the first, second, and third pass bands have either of the following relationships: third pass band<second pass band<first pass band, and third pass band<first pass band<second pass band. In other words, the multiplexer 21 is effective when the third pass band is lowest of the first, second, and third pass bands.

This is because the matching circuit 8A can suppress transmission of signals in the third pass band, which is relatively lowest, to the duplexer 6 and can effectively transmit signals in the first and second pass bands to the duplexer 6.

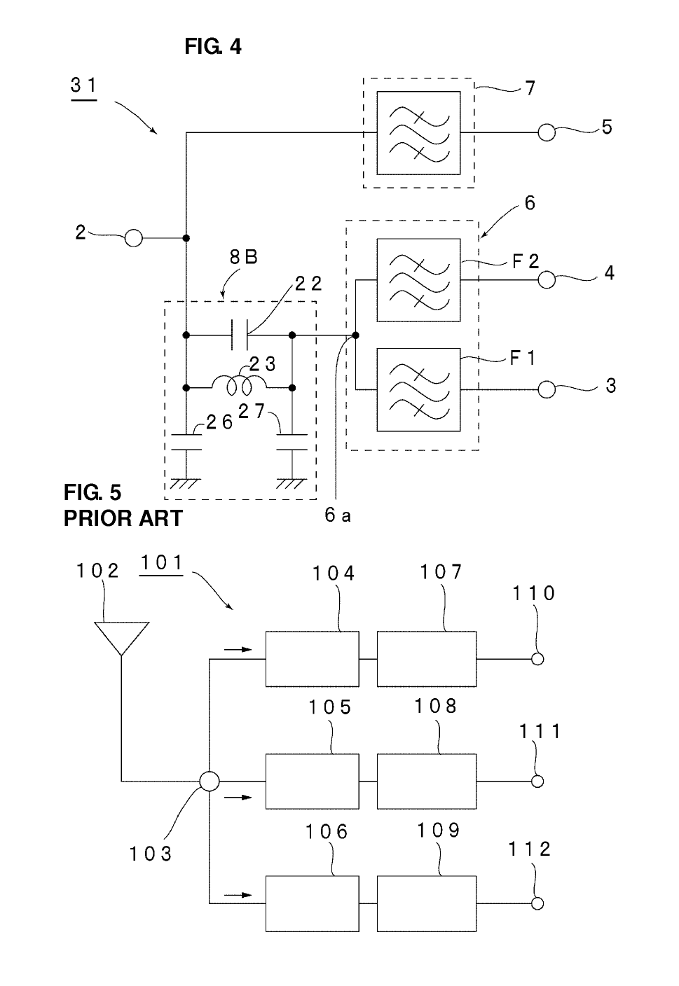

FIG. 4 is a schematic circuit diagram of a multiplexer according to a fourth preferred embodiment of the present invention.

The configuration of the multiplexer 31 is preferably the same as that of the multiplexer 21 of the third preferred embodiment except that a matching circuit 8B is connected in place of the matching circuit 8A in the multiplexer 21 of the third preferred embodiment. Therefore, the description other than that of the matching circuit 8B will be omitted by referring to the description of the third preferred embodiment.

In the present preferred embodiment, the matching circuit 8B is connected between the antenna terminal 2 and the duplexer 6. The matching circuit 8B includes first, second, and third capacitors 22, 26, and 27 and the first inductor 23. Specifically, the first capacitor 22 is connected between the antenna terminal 2 and the common connection point 6a of the duplexer 6. The first inductor 23 is connected in parallel with the first capacitor 22. The second capacitor 26 is connected between the antenna terminal 2 and the ground potential. The third capacitor 27 is connected between the common connection point 6a and the ground potential.

The matching circuit 8B is configured such that the phases of the first and second band-pass filters F1 and F2 of the duplexer 6 are in an open state in the third pass band, which is the pass band of the third band-pass filter 7.

The matching circuit 8B includes an LC resonance circuit including the first capacitor 22 and the first inductor 23, and the second and third capacitors 26 and 27 connected in parallel. The matching circuit 8B thus functions as a low-pass filter.

Therefore, the multiplexer 31 is effective when the first, second, and third pass bands have either of the following relationships: first pass band<second pass band<third pass band, and second pass band<first pass band<third pass band. In other words, the multiplexer 31 is effective when the third pass band is highest of the first, second, and third pass bands. This is because the matching circuit 8B can suppress transmission of signals in the third pass band, which is relatively highest, to the duplexer 6 and can effectively transmit signals in the first and second pass bands to the duplexer 6.

As is apparent from the first to fourth preferred embodiments, each of the multiplexers according to the present invention may include no matching circuits or may include a matching circuit, as necessary, between the antenna terminal 2 and the duplexer 6 and between the antenna terminal 2 and the third band-pass filter 7. In either case, it is only necessary that one duplexer and one band-pass filter be included in a triplexer. It is thus possible to reduce the size of the multiplexer.

Each of the multiplexers according to various preferred embodiments of the present invention preferably is connected to an antenna in the cellular phone. For impedance matching between the multiplexer and the antenna, there may be an impedance matching inductor connected between the antenna and the antenna terminal.

Although the multiplexers 1, 11, 21, and 31 of the first to fourth preferred embodiments each are preferably a triplexer that includes three band-pass filters having different pass bands, the present invention is not limited to this. Specifically, in addition to the configuration of each of the preferred embodiments described above, there may be one or more band-pass filters and one or more duplexers that are connected to the antenna terminal and are in parallel with the duplexer 6 and the third band-pass filter 7.

The multiplexers 1, 11, 21, and 31 of the first to fourth preferred embodiments each can be suitably used as, for example, a branching filter in which a receiving filter or a transmitting filter is shared by multiple communication systems.

For example, in a multiplexer included in a cellular phone that supports UMTS-BAND1 and UMTS-BAND4, the duplexer 6 can include a transmitting filter for UMTS-BAND1 and a receiving filter for both UMTS-BAND1 and UMTS-BAND4, and the third band-pass filter 7 can include a transmitting filter for UMTS-BAND4.

In a multiplexer included in a cellular phone that supports UMTS-BAND1 and UMTS-BAND10, the duplexer 6 can include a transmitting filter for UMTS-BAND1 and a receiving filter for both UMTS-BAND1 and UMTS-BAND10, and the third band-pass filter 7 can include a transmitting filter for UMTS-BAND10.

The multiplexers according to various preferred embodiments of the present invention are applicable not only to cellular phones that support specific communication systems, but widely to cellular phones that support multiple bands and multiple types of communication systems.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer comprising:
an antenna terminal;
a duplexer including a first band-pass filter and a second band-pass filter; and
a third band-pass filter; wherein
the first band-pass filter has a first pass band;
the second band-pass filter has a second pass band different from the first pass band;
the third band-pass filter has a third pass band different from the first and second pass bands; and
the duplexer and the third band-pass filter are connected in parallel to the antenna terminal.

2. The multiplexer according to claim 1, wherein the third pass band is located on a frequency side lower or higher than the first and second pass bands.

3. The multiplexer according to claim 1, further comprising a first matching circuit connected between the duplexer and the antenna terminal.

4. The multiplexer according to claim 3, wherein the third pass band is located on a frequency side lower than the first and second pass bands, and the first matching circuit is a high-pass filter.

5. The multiplexer according to claim 3, wherein the third pass band is located on a frequency side higher than the first and second pass bands, and the first matching circuit is a low-pass filter.

6. The multiplexer according to claim 1, further comprising a second matching circuit connected between the third band-pass filter and the antenna terminal.

7. The multiplexer according to claim 1, wherein phases of the first and second band-pass filters of the duplexer as viewed from the antenna terminal are in an open state in the third pass band, and a phase of the third band-pass filter as viewed from the antenna terminal is in an open state in the first and second pass bands.
